(19) United States
(12) Patent Application Publication
(10) Pub. No.: US 2012/0162882 A1
(43) Pub. Date: Jun. 28, 2012

(54) SHEET METAL FRAME AND ELECTRONIC APPARATUS INCLUDING THE SAME

(75) Inventor: Yasuhiro MIYAKE, Osaka (JP)

(73) Assignee: KYOCERA MITA CORPORATION, Osaka (JP)

(21) Appl. No.: 13/339,186

(22) Filed: Dec. 28, 2011

(30) Foreign Application Priority Data
Dec. 28, 2010 (JP) 2010-292156

(51) Int. Cl. H05K 7/00; H05K 5/02

(52) U.S. Cl. 361/679.01; 312/223.1

(57) ABSTRACT

In a surface of a frame main body (50a) of a support frame (50), there are formed drawn portions (51a to 51e) for increasing rigidity of the support frame (50) to prevent a warp and a distortion thereof. Further, linear groove portions (53) are engraved so as to surround the drawn portions (51a to 51e).

This application is based upon and claims the benefit of priority from the corresponding Japanese Patent Application No. 2010-292156 filed on Dec. 28, 2010, the entire contents of which are incorporated herein by reference.

### BACKGROUND OF THE DISCLOSURE

1. Field of the Disclosure

The present disclosure relates to a sheet metal frame to be used for an electronic apparatus such as an image forming apparatus, and more particularly, to an improvement in surface accuracy and strength of a sheet metal frame.

2. Description of Related Art

Conventionally, a sheet metal frame has been widely used as a frame that constructs a casing of an electronic apparatus, or as a frame for supporting electronic components arranged inside the casing. The sheet metal frame has excellent rigidity, but as a sheet metal becomes thicker, the electronic apparatus becomes heavier, which raises a problem of a cost disadvantage.

Therefore, there is employed a method of forming a drawn portion in the sheet metal frame so as to increase the rigidity while reducing the thickness of the sheet metal frame as small as possible. For example, there is known an electronic apparatus frame having two drawn portions provided across a stay portion, to thereby increase the rigidity and strength of the frame and also enhance an anti-shock characteristic thereof. Further, there is known a structure in which an embossed portion (drawn portion) is provided in at least part of a frame of an image reading section mounted on an image forming apparatus.

By the way, in the case of forming a drawn portion in a sheet metal member as described above, there is a problem in that the sheet metal member is distorted to result in a decrease in surface accuracy. Specifically, when a drawn portion 102 is formed in a sheet metal frame 101 as illustrated in FIG. 6, a material of a corner portion 102a situated on a recessed surface side of the drawn portion 102 is stretched and a material of a corner portion 102b situated on a projecting surface side of the drawn portion 102 is compressed. As a result, the cross section of the sheet metal frame 101 is distorted into a V-shape.

### SUMMARY OF THE DISCLOSURE

In view of the above-mentioned problem, the present disclosure has an object to provide a sheet metal frame having high rigidity and high surface accuracy obtained by eliminating, using a simple method, a distortion occurring due to formation of a drawn portion, and to provide an electronic apparatus including the sheet metal frame.

In order to achieve the above-mentioned object, according to an aspect of the present disclosure, the sheet metal flame of the present disclosure has a frame main body formed into a flat plate shape, and at least one drawn portion formed in the frame main body. In the sheet metal flame, linear groove portions are engraved at constant distances from outer edge portions of the at least one drawn portion so as to sandwich the at least one drawn portion between at least opposing sides.

Further features and advantages of the present disclosure will become apparent from the description of embodiments given below.

### BRIEF DESCRIPTION OF THE DRAWINGS

FIG. 1 is a schematic view of an image forming apparatus having a support frame 50 mounted thereon according to an embodiment of the present disclosure.

FIG. 2 is a perspective view of the support frame 50 as viewed from above according to the embodiment of the present disclosure.

FIG. 3 is a partially enlarged view of a periphery of a corner portion of the support frame 50 according to the embodiment of the present disclosure.

FIG. 4 is a partially enlarged view of a periphery of a drawn portion 51a of the support frame 50 according to the embodiment of the present disclosure.

FIG. 5 is a partial sectional view of the periphery of the drawn portion 51a of the support frame 50 according to the embodiment of the present disclosure.

FIG. 6 is a partial sectional view illustrating a state in which a drawn portion 102 is formed in a conventional sheet metal frame 101.

### DETAILED DESCRIPTION OF PREFERRED EMBODIMENTS

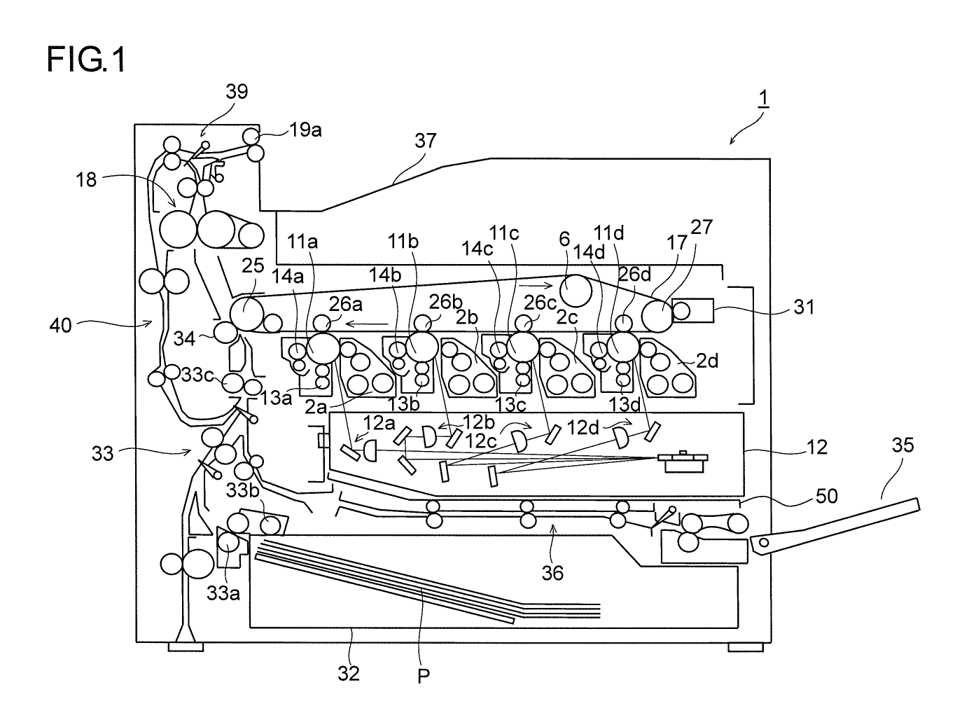

Hereinafter, an embodiment of the present disclosure is described with reference to the drawings. FIG. 1 is a schematic plan view illustrating a structure of an image forming apparatus including a support frame 50 serving as a sheet metal frame of the present disclosure. An image forming apparatus 1 is a tandem-type color printer, and includes photosensitive conductor drums 11a to 11d corresponding to respective colors of cyan, magenta, yellow, and black, the photosensitive conductor drums 11a to 11d being rotatably disposed. As the photosensitive conductor drums 11a to 11d, for example, there is used an organic photosensitive conductor member (OPC photosensitive conductor member) including an organic photosensitive conductor layer, or an amorphous silicon photosensitive conductor member including an amorphous silicon photosensitive conductor layer. On the periphery of the photosensitive conductor drums 11a to 11d, developing devices 2a to 2d, an exposure unit 12, charging devices 13a to 13d, and cleaning devices 14a to 14d are disposed, respectively.

The developing devices 2a to 2d are arranged on the right side of the photosensitive conductor drums 11a to 11d and are opposed to the photosensitive conductor drums 11a to 11d, respectively. The developing devices 2a to 2d supply toner to the photosensitive conductor drums 11a to 11d, respectively. The charging devices 13a to 13d are arranged on the upstream side of the developing devices 2a to 2d with respect to the rotation direction of the photosensitive conductor drums 11a to 11d and are opposed to the surfaces of the photosensitive conductor drums 11a to 11d, respectively. The charging devices 13a to 13d uniformly charge the surfaces of the photosensitive conductor drums 11a to 11d, respectively.

The exposure unit 12 is used for scanning and exposing to light the respective photosensitive conductor drums 11a to 11d based on image data of characters and pictures which are input from a personal computer or the like to an image input section (not shown), and is provided under the developing devices 2a to 2d. Inside the exposure unit 12, a laser light source, a polygon mirror, and reflection mirrors and lenses corresponding to the respective photosensitive conductor drums 11a to 11d are provided. Laser beams emitted from the laser light source are respectively applied to the surfaces of the photosensitive conductor drums 11a to 11d from the downstream side of the charging devices 13a to 13d with respect to the rotation direction of the photosensitive conductor drums 11a to 11d via the polygon mirror, and the reflection mirrors and the lenses. With the applied laser beams, electrostatic latent images are formed on the surfaces of the photosensitive conductor drums 11a to 11d, and those electrostatic latent images are developed into toner images by the developing devices 2a to 2d, respectively. The exposure unit 12 is supported against the support frame 50 made of a sheet metal, and is removable from and mountable on the main body of the image forming apparatus 1.

An endless intermediate transfer belt 17 is looped around a tension roller 6, a driver roller 25, and a driven roller 27. The driver roller 25 is driven to rotate by a motor (not shown), and the intermediate transfer belt 17 is driven to circulate by the rotation of the driver roller 25.

The photosensitive conductor drums 11a to 11d are arranged under the intermediate transfer belt 17 so as to come into contact with the intermediate transfer belt 17, and to adjoin each other along a conveyance direction (arrow direction of FIG. 1). Primary transfer rollers 26a to 26d are opposed to the photosensitive conductor drums 11a to 11d, respectively, while nipping the intermediate transfer belt 17. The primary transfer rollers 26a to 26d come into press contact with the intermediate transfer belt 17 to form a primary transfer section. In this primary transfer section, the toner images on the respective photosensitive conductor drums 11a to 11d are sequentially transferred onto the intermediate transfer belt 17 at predetermined timings in accordance with the rotation of the intermediate transfer belt 17. Accordingly, on the surface of the intermediate transfer belt 17, there is formed a full-color toner image obtained by the four-color, that is, cyan, magenta, yellow, and black toner images superimpose.

A secondary transfer roller 34 is opposed to the driver roller 25 while nipping the intermediate transfer belt 17. The secondary transfer roller 34 comes into press contact with the intermediate transfer belt 17 to form a secondary transfer section. In this secondary transfer section, the full-color toner image on the surface of the intermediate transfer belt 17 is transferred onto a paper sheet P. After the transfer of the full-color toner image, a belt cleaning device 31 removes the toner remaining on the intermediate transfer belt 17.

At the lower part of the image forming apparatus 1, a sheet feeding cassette 32 for receiving the paper sheet P is disposed, and on the right side of the sheet feeding cassette 32, a stack tray 35 for manually feeding a paper sheet is disposed. On the left side of the sheet feeding cassette 32, a first sheet conveyance path 33 for conveying the paper sheet P fed from the sheet feeding cassette 32 to the secondary transfer section of the intermediate transfer belt 17 is disposed. Further, on the left side of the stack tray 35, a second sheet conveyance path 36 for conveying the paper sheet fed from the stack tray 35 to the secondary transfer section is disposed. Further, at the upper left part of the image forming apparatus 1, a fixing section 18 for performing fixing processing on the paper sheet P having an image formed thereon, and a third sheet conveyance path 39 for conveying the paper sheet having undergone the fixing processing to a sheet delivery section 37 are disposed.

The sheet feeding cassette 32 is drawable to the outside of the main body of the image forming apparatus 1 (toward the front side of the drawing sheet of FIG. 1) so that paper sheets are refillable. The paper sheets P received on the sheet feeding cassette 32 are fed one by one toward the first sheet conveyance path 33 by a pickup roller 33b and a handling roller 33a.

The first sheet conveyance path 33 and the second sheet conveyance path 36 join at a position before reaching a registration roller pair 33c, and the paper sheet P is conveyed to the secondary transfer section by the registration roller pair 33c with a proper timing adjusted between the image forming operation at the intermediate transfer belt 17 and the sheet feeding operation. Onto the paper sheet P conveyed to the secondary transfer section, the full-color toner image on the intermediate transfer belt 17 is secondarily transferred by the secondary transfer roller 34 having a bias potential applied thereto, and the resultant paper sheet P is conveyed to the fixing section 18.

The fixing section 18 includes a fixing belt to be heated by a heater, a fixing roller held in contact with the inner side of the fixing belt, and a pressure roller disposed to come into press contact with the fixing roller while nipping the fixing belt. The fixing section 18 heats and pressurizes the paper sheet P having the toner image transferred thereto to perform fixing processing. After the toner image is fixed to the paper sheet P by the fixing section 18, the paper sheet P is, when needed, reversed on a fourth sheet conveyance path 40, and another toner image is secondarily transferred onto the back side of the paper sheet by the secondary transfer roller 34 and fixed thereto by the fixing section 18. The paper sheet having the toner image fixed thereto passes through the third sheet conveyance path 39 and is delivered to the sheet delivery section 37 by a delivery roller pair 19a.

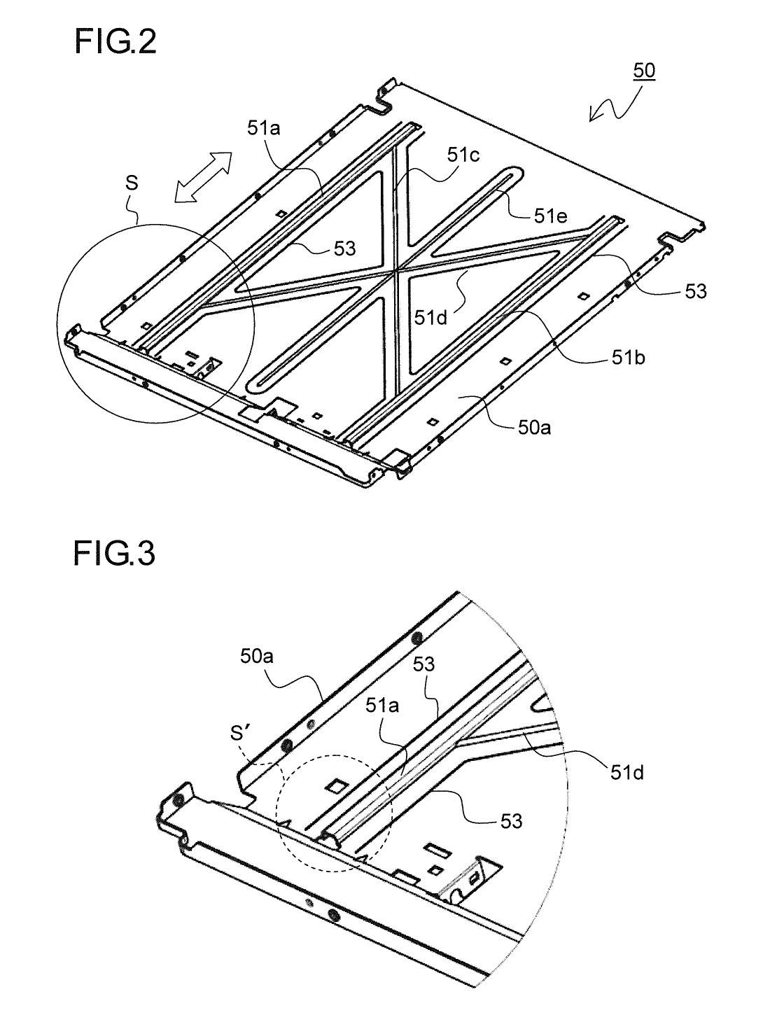

FIG. 2 is a perspective view of the support frame 50 for supporting the exposure unit 12. FIG. 3 is a partially enlarged view of a corner portion of the support frame 50 (inside a solid line circle S of FIG. 2). The support frame 50 includes a frame main body 50a formed into a flat plate shape and formed of an electrolytic zinc-coated steel sheet (SECC). The support frame 50 supports the lower surface of the exposure unit 12 (see FIG. 1) in the main body of the image forming apparatus 1 when the exposure unit 12 is inserted and removed, and guides the removable exposure unit 12 to a predetermined position in the main body of the image forming apparatus 1. Note that, the exposure unit 12 is not fixed to the support frame 50 but is fixed to a side surface frame (not shown) inside the image forming apparatus 1 with screws or the like.

In the surface of the frame main body 50a, there are formed drawn portions 51a to 51e for increasing rigidity of the support frame 50 to prevent a warp and a distortion thereof. The drawn portions 51a and 51b are formed along the two opposing side edges of the frame main body 50a. Further, the drawn portions 51c to 51e are formed radially from the center of the frame main body 50a, and the drawn portions 51c and 51d extend up to the drawn portions 51a and 51b. The drawn portions 51a to 51e are provided by, for example, subjecting the frame main body 50a to a drawing process using a press machine.

The drawn portions 51a and 51b are provided to extend along the inserting and removing directions of the exposure unit 12 (directions indicated by the white arrow of FIG. 2), and serve also as guide rails to be used when the exposure unit 12 is inserted and removed along the support frame 50. The shape of the drawn portions 51c to 51e is not particularly limited, but when the drawn portions to be provided are set as long in the surface direction of the frame main body 50a as possible, the structure of the support frame 50 becomes more resistant to a warp and a deflection. In this embodiment, the drawn portions 51c to 51e are arranged radially to obtain such a structure that a warp and a distortion do not easily occur even in a case where loads are applied to the support frame 50 from various directions.

Further, linear groove portions 53 are engraved so as to surround the drawn portions 51a to 51e. At the bent portions formed at the time of forming each of the drawn portions 51a to 51e, a compressive stress is generated on the inner side and a tensile stress is generated on the outer side. Those compressive stress and tensile stress become larger toward the surface of the sheet metal, and emerge as a distortion of the frame main body 50a. Therefore, the groove portions 53 are engraved after the drawn portions 51a to 51e are formed, and accordingly the stresses generated on the surface of the sheet metal are dispersed by the groove portions 53. As a result, the distortion of the frame main body 50a can be corrected.

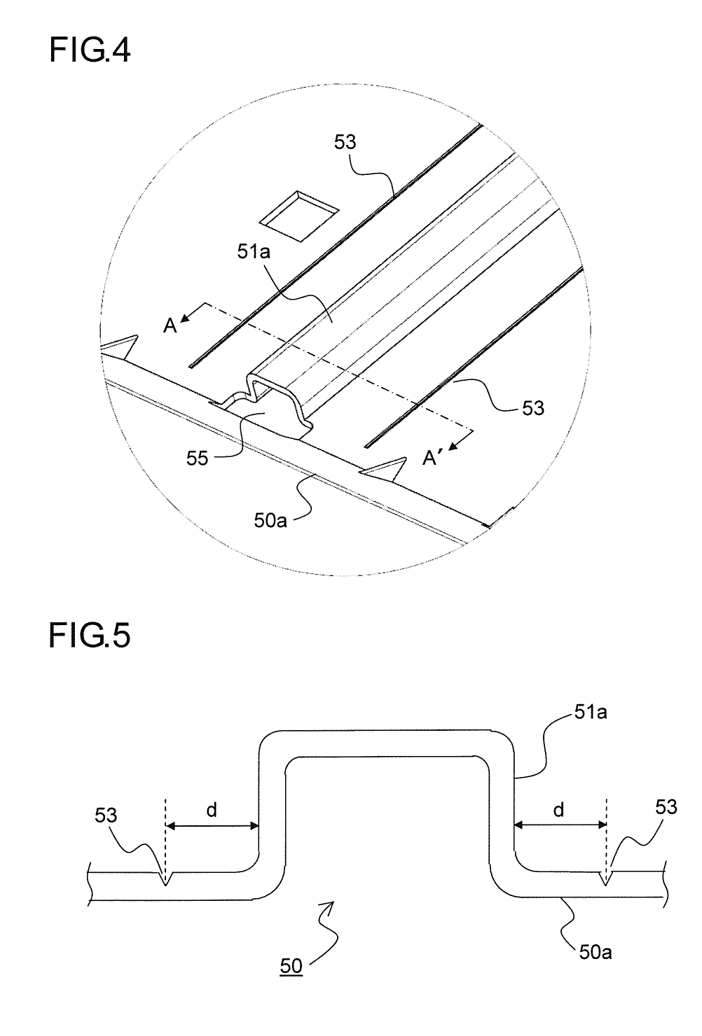

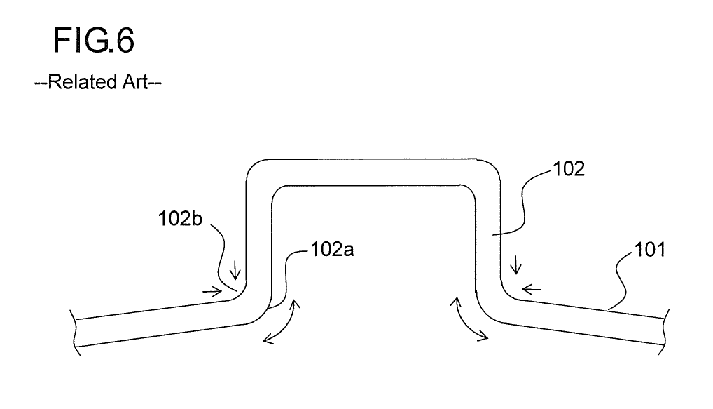

The groove portions 53 are engraved at constant distances from the outer edge portions of each of the drawn portions 51a to 51e, and surround the substantially entire region of the drawn portions 51a to 51e except for both end portions of the drawn portions 51a and 51b. This is because openings 55 (see FIG. 4) are formed at both the end portions of the drawn portions 51a and 51b, and hence the compressive stress and the tensile stress are not generated. Thus, there is no need to engrave the groove portions 53 at those portions.

Further, the groove portions 53 produce a greater effect of correcting the distortion as the range of surrounding the drawn portions 51a to 51e becomes wider, and the distortion correcting effect becomes greatest when the drawn portions 51a to 51e are completely surrounded. Note that, in order to correct the distortion to an insignificant level in practical use, the groove portions 53 do not need to completely surround the drawn portions 51a to 51e, but the groove portions 53 need to be engraved at least along the two directions opposed across the drawn portions 51a to 51e.

FIG. 4 is a partially enlarged view of a periphery of an end portion of the drawn portion 51a (inside a broken line circle S′ of FIG. 3). FIG. 5 is a partial sectional view (sectional view taken along the arrow AN of FIG. 4) of the periphery of the drawn portion 51a. In this embodiment, the groove portions 53 are engraved from a projecting side of the drawn portions 51a to 51e (from the upper side of FIG. 5). The distortion correcting effect is obtained also in a case where the groove portions 53 are engraved from a recessed side of the drawn portions 51a to 51e, but the distortion correcting effect is greater when the groove portions 53 are engraved from a direction opposite to the direction in which the drawn portions 51a to 51e are formed through the drawing process (bottom-to-top direction of FIG. 5). Further, distances d each ranging from the outer edge portion of each of the drawn portions 51a to 51e to the groove portion 53 are set substantially equal to each other on both sides of each of the drawn portions 51a to 51e. Accordingly, the distortion occurring due to formation of the drawn portions 51a to 51e can be corrected substantially equally on both sides of each of the drawn portions 51a to 51e.

The distance d ranging from the outer edge portion of each of the drawn portions 51a to 51e to the groove portion 53 and the depth of the groove portion 53 may be set as appropriate depending on the thickness, the material, and the like of the sheet metal that forms the frame main body 50a, but when the distance d is excessively large or the depth of the groove portion 53 is excessively small, the distortion correcting effect becomes poor. On the other hand, when the depth of the groove portion 53 is excessively large, the strength of the support frame 50 is decreased at the part at which the groove portions 53 are provided. In this embodiment, the frame main body 50a has a thickness of 0.8 mm, the groove portion 53 has a depth of 0.3 mm, and the distance d ranges from 5 mm to 10 mm.

Besides, the present disclosure is not limited to the above-mentioned embodiment, and various modifications may be made thereto without departing from the spirit of the present disclosure. For example, the description of this embodiment is directed to the support frame 50 for the exposure unit 12 as an example of the sheet metal frame, but needless to say, the present disclosure is also applicable to a sheet metal frame arranged at a different part of the image forming apparatus 1 or a sheet metal frame for an electronic apparatus other than the image forming apparatus.

Further, in the above-mentioned embodiment, the drawn portions 51a to 51e having a rib shape are formed in the support frame 50, but the shape and size of the drawn portions may also be modified as appropriate within the scope of the object of the present disclosure, depending on the position of arrangement of the sheet metal frame and the purpose of arrangement.

The present disclosure is applicable to a sheet metal frame to be used for an electronic apparatus such as an image forming apparatus, and in the sheet metal frame, linear groove portions are engraved at constant distances from the outer edge portions of each drawn portion formed in a frame main body so as to sandwich the drawn portion between at least opposing sides. By applying the present disclosure, it is possible to increase the rigidity and surface accuracy of the sheet metal frame with a simple structure, and to provide an electronic apparatus which is reduced in thickness and weight as compared to the conventional electronic apparatus and has an improved arrangement accuracy of components and an excellent strength.

What is claimed is:

1. A sheet metal frame, comprising:
a frame main body formed into a flat plate shape;
at least one drawn portion foamed in the frame main body; and
groove portions engraved into a linear shape in the frame main body at constant distances from outer edge portions of the at least one drawn portion so as to sandwich the at least one drawn portion between at least opposing sides.

2. A sheet metal frame according to claim 1, wherein the groove portions are engraved at substantially equal distances from the outer edge portions of the at least one drawn portion.

3. A sheet metal frame according to claim 2, wherein the groove portions are engraved so as to surround a substantially entire region of the at least one drawn portion.

4. A sheet metal frame according to claim 3, wherein the groove portions are engraved from a projecting side of the at least one drawn portion.

5. A sheet metal frame according to claim 1, wherein the at least one drawn portion is formed radially from a center of the frame main body.

6. An electronic apparatus, comprising the sheet metal frame according to claim 1.
